(19) United States
(12) Patent Application Publication
(10) Pub. No.: US 2018/0048484 A1
(43) Pub. Date: Feb. 15, 2018

(54) SENSOR HUB WITH POWER MANAGER

(71) Applicant: Embertec Pty Ltd, Dulwich, South Australia (AU)

(72) Inventor: Domenico Gelonese, Dulwich, South Australia (AU)

(21) Appl. No.: 15/546,695

(22) PCT Filed: Jan. 29, 2016
(86) PCT No.: PCT/AU2016/000017

§ 371 Date: Jul. 27, 2017

(30) Foreign Application Priority Data
Jan. 30, 2015 (AU) 2015900282

(51) Int. Cl. H04L 12/28

(52) U.S. Cl. CPC H04L 12/2825; H04L 12/283; G01R 21/133

(57) ABSTRACT

A computer system for household energy management having a sensor hub including environmental sensors for sensing the environment within a household, a usage data communications link providing a data link to. a device adapted to measure the electricity consumption of the household and a remote data communications link providing a data link to a remotely located computer processor, programmed to provide an intelligent power manager wherein the intelligent power manager receives usage data describing the energy consumption of the household from the sensor hub approximately in real time.

### TECHNICAL FIELD

This invention relates to a system for managing household energy including an intelligent sensor unit.

### BACKGROUND OF THE INVENTION

The following references to and descriptions of prior proposals or products are not intended to be and are not to be construed as statements or admissions of common general knowledge in the art. In particular, the following prior art discussion does not relate to what is commonly or well known by the person skilled in the art, but may assist in the understanding of the inventive step of the present invention, of which the identification of pertinent prior proposals is but one part.

There is currently world-wide concern about the level of use of electrical energy for both domestic and commercial uses. In part this concern is based on the greenhouse gas production associated with the generation of electrical energy, and the contribution of that greenhouse gas to anthropogenic global warming. There is also a concern for the capital cost involved in building the electricity generating plants and electricity distribution networks required to generate and distribute an increasing amount of electricity.

A significant contributor to the energy use of households is the audio visual equipment including multiple devices such as televisions, television decoders, television recorders and sound equipment now found in virtually all homes.

Efforts have been made to reduce or control the use of energy by television receivers and associated audio visual equipment, in particular with the use of standby power controllers, and these have met with considerable success. However, the inflexibility of control of standby power controllers has been a barrier to their adoption and use.

### DISCLOSURE OF THE INVENTION

Accordingly, in a first aspect this invention provides a sensor hub for household energy management including environmental sensors for sensing the environment within a household, including a usage data communications link which provides a data link to a device adapted to measure the electricity consumption of the household, which may be, among other devices, a Smartmeter or a current clamp, further including a remote data communications link providing a data link to a remotely located intelligent power manager.

In preference, the environmental sensors are one or more of a temperature sensor, an infra-red detector, a light detector and a proximity detector.

In preference, there is a user interface data link which provides a data link to a mobile computing device, said mobile computing device running software to provide a user interface for the sensor hub.

In preference, there is a control communications link which provides a data link to a standby power controller.

In preference, the sensor hub includes a detector adapted to detect use of an audio visual remote control unit, and to provide an indication of said detection to the standby power controller.

In preference, the indication of detection causes a timer to be reset, the standby power controller being adapted to remove power from controlled power outlets when the timer indicates that a defined period has elapsed since the last detected use of the remote control.

In a further form, the invention may be said to lie in a computer system for household energy management including the sensor hub, further including a computer processor remote from the household, programmed to provide an intelligent power manager wherein the intelligent power manager receives usage data describing the energy consumption of the household from the sensor hub approximately in real time.

In preference, the intelligent power manager analyses the usage data to ascertain the energy use and identity of at least one individual appliance in the household.

In reference, the intelligent power manager receives from the household information including household characteristics being any one or more of household energy usage, household makeup, household dwelling description and household geographic location.

The intelligent power manager, having determined that a more efficient version of the at least one appliance is available, provides a recommendation of a replacement appliance to the sensor hub for display to a householder.

In preference, the intelligent power manager receives household information and usage data from a plurality of households.

In preference, the intelligent power manager analyses the household information from the plurality of households to determine similar households based on a defined degree of similarity for one or more household characteristics, the intelligent power manager determining an average value for an element of the usage data from the similar households, determining variance information being a description of the difference from that average for an individual household, and transmitting that variance information to the sensor hub in that household for display to a householder.

The intelligent power manager analyses the household information and the usage data to determine one or more reasons that a first household has greater energy usage than other households with similar household information, the intelligent power manager communicating the reason to the sensor hub of the first household, allowing the household to make changes to save energy.

In preference, the changes to be made are changes to household habits or energy usage patterns.

In preference, in addition or in the alternative, the changes to be made are changes to household appliances or changes to the household dwelling.

In a further form the invention provides for standby power controller including a control data link to a sensor hub, wherein the standby power controller receives from the sensor hub indication of the use of an audio visual remote control in the vicinity of the sensor hub.

In preference, the standby power controller transmits data describing the operation of the standby power controller to the sensor hub.

The invention may also be said to lie in a standby power controller including a sensor hub wherein said sensor hub is adapted to detect use of an audio-visual remote control device.

### BRIEF DESCRIPTION OF THE DRAWINGS

The invention will now be described with reference to certain non-limiting embodiments in connection with the accompanying drawings in which:

FIG. 1 is a representation of a standby power controller incorporating the invention;

FIG. 2 shows a household including a standby power controller of the invention;

FIG. 3 shows a household including a sensor hub of the invention;

FIG. 4 shows a household information collection screen for an intelligent power manager;

FIG. 5 shows a home screen for an intelligent power manager;

FIG. 6 shows a tariff display screen for an intelligent power manager;

FIG. 7 shows a screen of an intelligent power manager showing a comparison with a typical household;

FIG. 8 shows a block diagram of the operating units of an embodiment of the invention.

### DETAILED DESCRIPTION OF THE DRAWINGS

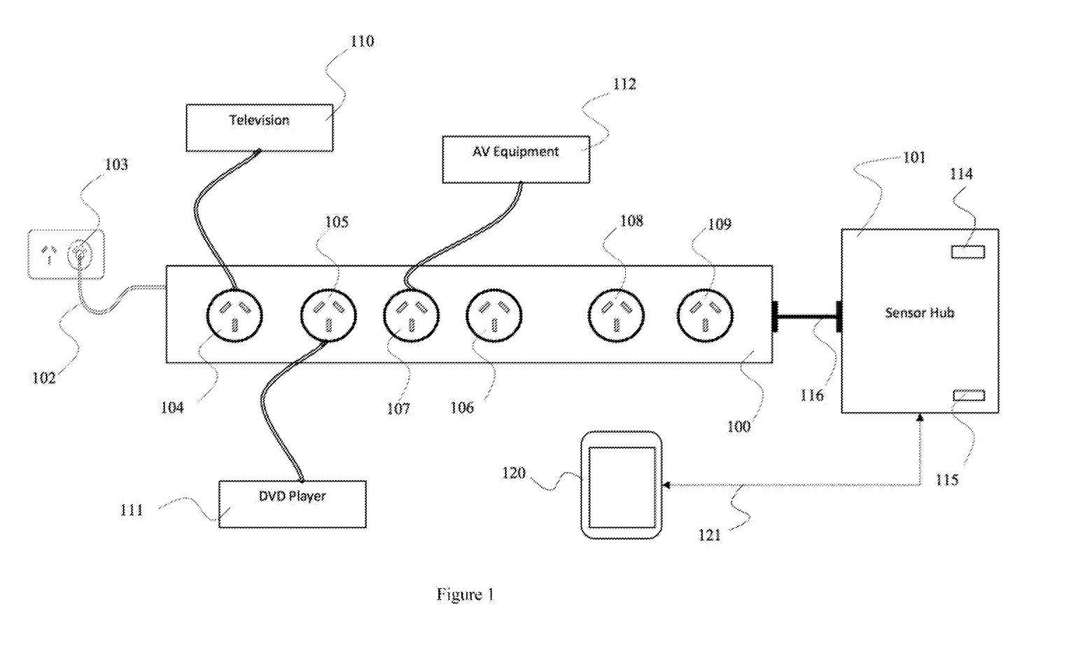

Referring first to FIG. 1, it is to be understood that this is a general representation of an installation including a standby power controller (SPC) including the invention and is illustrative only. It is not intended to limit the number or configuration of continually powered or switched or monitored main outlets, or of communication interfaces or other functional modules.

FIG. 1 shows a representation of an SPC including an embodiment of the current invention. An SPC is a device which controls the flow of electrical power to one or more connected appliances such that when one or more, or a particular one, of the connected appliances enters a low power consumption “standby” state, the electrical power supply to one, all or selected ones of the connected appliances is interrupted.

The SPC 100 receives electrical power from a General Purpose Outlet 103, via power cord 102.

The SPC includes Monitored and Controlled Outlets 104,105,106, 107. The SPC also includes Uncontrolled Outlets 108, 109. In general, any number of Monitored and Controlled outlets and Uncontrolled Outlets may be provided. In an embodiment, the Uncontrolled outlet may be absent.

Monitored and Controlled Outlet 104 supplies electrical power to a television 110. Further Monitored and Controlled Outlets 105, 106 may provide electrical power to other audio-visual equipment, for example a DVD player Ill and audio equipment 112. In an embodiment having only one Monitored and Controlled outlet, multiple devices may be powered from the one outlet using a powerstrip. In any embodiment, multiple devices may be powered from one Monitored and Controlled outlet using a powerstrip.

The SPC includes sensor hub 101 which is connected to SPC base unit 100 by wired data and power connection 116. Power for the sensor hub 101 is provided by connection 116. Data communication, using any convenient protocol, is also provided by control data link 116. In other embodiments, the sensor hub may be separately powered, and the control data link may be a wireless link.

The sensor hub includes a user interface which is provided as software running on a tablet computer, smartphone or general purpose computer, which is in data communication with the sensor hub, in a preferred embodiment by wireless means. In the illustrated embodiment, there is provided a smartphone 120 which is in data communication with the sensor hub via Bluetooth user information data link 121. Any other convenient protocol may be used.

In order to save energy the SPC operates to remove the power supply from Controlled and Monitored outlet 104 and hence from the attached television, whenever the television is detected to not be in use.

Modern television sets and other audio visual equipment, when turned “off” by the remote control, enter a low power “standby” state, in which energy is still consumed, although at a significantly lower level that when the device is nominally “on”. When the television is in this standby state it is not in use, and the power supply to it may be cut to save energy.

It is also the case that television sets may be left on for extended periods when no user is viewing the screen. This may happen when a user falls asleep in front of the television, or when a user, particularly a child or a teenager, simply leaves the vicinity of the television without turning the television off. This state may be termed “active standby”. In this state the television is not in use, and the power supply to it may be cut to save energy.

The SPC may detect that the television has entered a standby state by any convenient means or combination of means.

The SPC may also include a power sensor adapted to sense the power drawn through a Controlled and Monitored outlet. The power sensor detects characteristics of the power flow through the outlet. When the characteristic is such as to indicate that the television is in a standby mode the power to the Controlled and Monitored outlet 104, and hence to the attached television or monitor is interrupted.

The SPC may include any number of Controlled and Monitored outlets, which may be monitored and controlled individually or together.

The SPC includes means to detect that a user is interacting with the audio visual equipment and/or the television. The sensor hub includes IR Sensor 115 which receives R signals from a remote control associated with the television or other connected AV equipment. The sensor hub passes the information that an infra-red signal has been detected to the SPC via control data link 116.

It is likely that a user, when actively watching television, will periodically use the remote control to change channels, adjust volume, mute commercials, etc. Thus a remote control signal receiver, such as IR sensor 115 can be used as a usage sensor. If no remote control activity is detected by the IR sensor 115 for a period of time, the assumption may be made that the television is not in use, and the power supply to the Controlled and Monitored outlet 104, and hence to the television, is interrupted. This may be achieved by using a countdown timer which starts from a specific initial value equal to a particular time period, say one hour, and having this countdown time continuously decrement. Each detected use of the remote control will reset the countdown timer to the initial value. When the countdown time reaches zero, there has been no remote control activity for the time period, and the television is assumed to not be in active use and the electricity supply to the Controlled and Monitored outlet 104, and hence to the television, is interrupted. In other embodiments, the measurement of the period of time in which no remote control use has been detected may be by any convenient means, for example, a timer which counts upwards to a particular value.

It may be sufficient to determine that a user is present in the vicinity of the television in order to decide that the television should not be turned off. The sensor hub may include any suitable sensor which may be used for determining that a user is present and thus that power to the television should not be interrupted. These include, without limitation, passive IR sensors, ultrasonic sensors, cameras, any other passive or active movement sensors, and sound detectors.

Whatever means is used to determine that the television is on, but not in use, it is unlikely to be completely free of false positives, that is, determining that the television is in active standby and not in use when the television is in fact in use. If the television is turned off when a user is still watching a program, the user will be irritated. Repeated occurrences are likely to lead to the power control function of the SPC being bypassed, preventing power savings.

The SPC includes a warning capability. When the SPC determines that the television is in active standby, a warning is given to alert any user to the imminent shutdown of the power to the television. In the case where there is a false positive, that is, there is a user watching the television, the user may react to observing the warning by pressing a key on the remote control. The IR signal from the remote control is detected by the IR sensor 115 and the countdown timer is reset, preventing the power to the television being interrupted.

In the illustrated embodiment, the SPC communicates to the sensor hub that shutdown is imminent. The warning is given by the sensor hub flashing warning LED 114. In an embodiment the warning may be provided by the user interface which is provided by the smartphone 120, or directly by the SPC.

Other methods for warning of imminent shutdown of power to the television may be used. An audible warning tone may sound.

Uncontrolled power outlets 108, 109 are optionally provided to allow for power to be supplied to devices which should not have the power supply cut when the television is not in use. This outlet supplies power at all times when the SPC is plugged in. Any number of uncontrolled outlets may be provided.

Devices other than a television may be connected along with a television to the Controlled and Monitored outlets. In this case, the total load of all devices will be monitored for the characteristics indicating that all devices so connected are in a standby or unused state.

A third type of power outlet (not shown) may be provided. This non-monitored, controlled outlet is not monitored by the power sensor, so the power drawn by any load connected to the outlet does not contribute to the determination that the monitored load is in a standby or unused state. This outlet is controlled. When power is interrupted to the monitored, controlled outlet 108, power is also interrupted to this outlet.

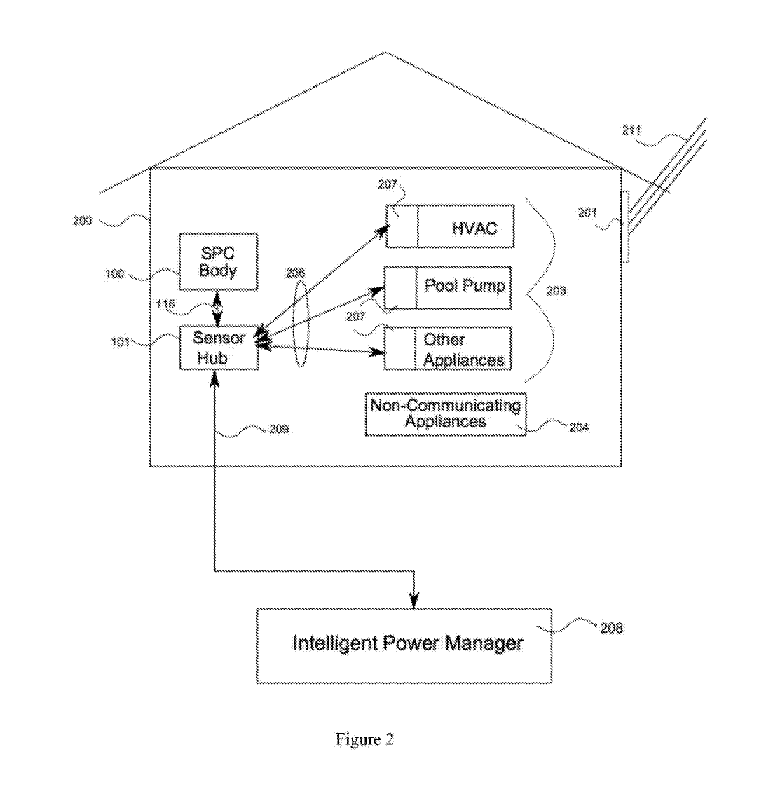

FIG. 2 shows a household, illustrating the function of the sensor hub 101. The sensor hub 101 includes a communication transceiver which allows the sensor hub to communicate with corresponding transceivers in electrical appliances 203 in the consumer premises. In the illustrated embodiment, the communication is via Zigbee links 206. Other communications links may be used, including other wireless protocols such as wi-fi. Alternative communication means such as wired Ethernet or powerline signalling systems may be used. A combination of communication links may be used, such that the sensor hub has multiple communication transceivers.

The sensor hub may include a user interface which is provided as software running on a tablet computer, smartphone or general purpose computer, which is in data communication with the sensor hub, in a preferred embodiment by wireless means.

In an alternative embodiment, the sensor hub includes a display, and the user interface is provided as an integral part of the sensor hub.

The sensor hub 101 is in data communication with a device which is able to measure the electricity consumption of the household in real time or with a high degree of granularity. In a preferred embodiment, this device is a Smartmeter 201. Electricity is provided to the household from distribution system 211, via Smartmeter 201. The Smartmeter is a device which measures the electricity consumption of the household for billing purposes. The Smartmeter is able to communicate this metering data to the household's energy retailer for billing purposes, but may also communicate the data to the sensor hub.

In an embodiment, at least one of the appliances 203 is associated with an Appliance Communications Module (ACM) 207 which includes a transceiver able to communicate with the sensor hub 101. The ACM is able to determine, and to communicate to the sensor hub, the current power usage of the associated appliance.

In an alternative embodiment, usage data for individual appliances 204 which are not able to communicate directly with the sensor hub may be determined by analysis of the electricity usage data from the Smartmeter. The usage of particular appliances may be identified by the characteristic signature of the electricity consumption caused by that use. The ACM is not essential, nor is the automatic identification of individual appliances and the usage patterns of those appliances. Improved information can be provided to the householder where this information is available.

The sensor hub is also in data communication with a remote Intelligent Power Manager (IPM) 208. In a preferred embodiment, this communication is via a generic broadband internet connection 209, provided by the household. In other embodiments, communication may be by any convenient method, including without limitation, a Zigbee network, a mobile data network, and a dial-up internet connection.

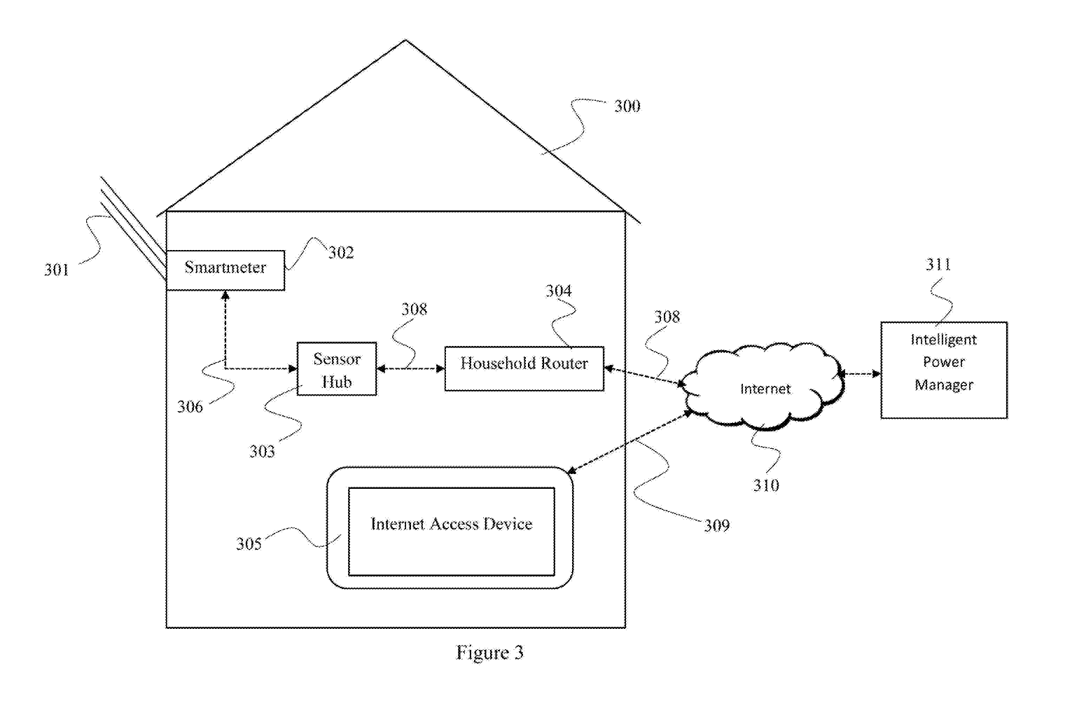

FIG. 3 shows a block diagram representation of a household including the sensor hub. The household 300 is provided with electricity from distribution system 301. The incoming electrical energy is recorded by Smartmneter 302. The Smartmeter 302 is in data communications with a sensor hub 303 via usage data communications link 306. Usage data communications link is preferably a wireless link, which may be provided by any convenient protocol. In the illustrated embodiment, this is a ZigBee wireless link.

The sensor hub is in wireless communication with Intelligent Power Manager 311 via remote data communications link 308. Remote data communications link is created by a wireless link to the household router 304, which provides access to the public internet 310, and hence to intelligent power manager 311.

There is also provided an internet access device 305. This may be any device capable of accessing the internet and displaying a user interface. Without limitation, this may include a desktop computer, a mobile computing device, a smartphone or a tablet computer.

The internet access device is in data communication with the intelligent power manager (IPM) 311 via communications link 309 which includes the public internet 310.

The IPM is a remote computer processor which is in communication with multiple sensor hubs situated at multiple households. The IPM is able to record and analyse data on electricity consumption and where available, individual appliance electricity consumption, from multiple households, in preference, a large number of households.

The internet access device provides a user interface for the IPM, which in a preferred embodiment is provided by running an internet browser which displays a user interface from the IPM. In other embodiment, the internet access device may run an App which provides the user interface locally, to display information from the IPM.

The IPM also records, where available, information regarding the make-up of the households, the appliances in each household, and the geographic location of each household.

The IPM monitors and tracks the energy usage patterns of a particular household and compares this data to similar sized homes preferably in real time, or at intervals significantly less than the household electricity billing interval, to provide the basis for householders to compare their energy usage with that of others during particular time periods.

Data from the household on energy usage and the other data concerning household make-up which is of use to compare homes and better profile their energy usage is encrypted and stored in the IPM.

The householder can then access their energy usage information from the IPM at any time to assess their energy usage over certain time periods, i.e. over the last hour, 24 hours, week, month, as desired.

This information is displayed by the user interface on the internet access device 305.

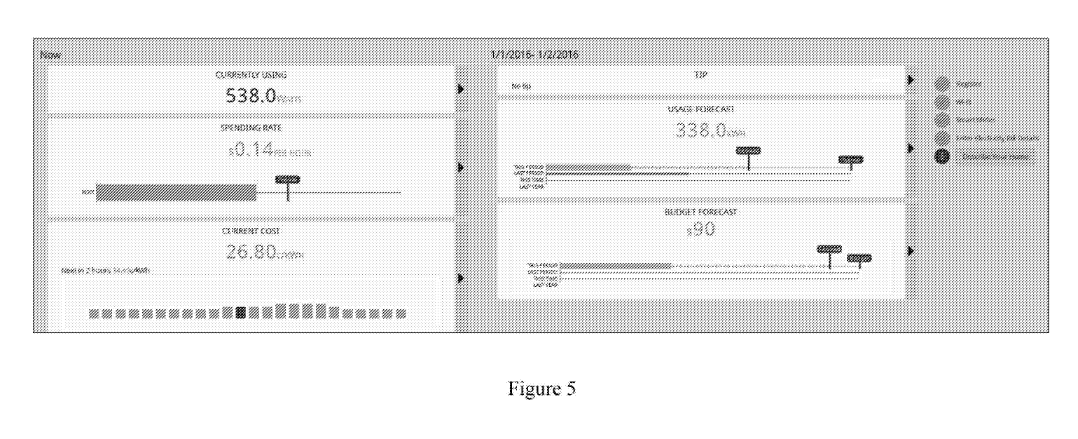

FIG. 5 shows a dashboard display from an IPM summarising the current energy use position of a household. It can be seen that the current energy use in watts is displayed, in the illustration, 538.0 watts. The cost of the energy use is displayed in dollars per hour, in the illustration $0.14, based on the current cost of electricity shown, in the illustration 26.80 cents per kilowatt hour.

The dashboard information concerning cost and budget requires that the IPM know the tariff rate applicable to the household. Tariffs may not be constant over the day, week, month or any other time period. The applicable tariff details may be entered by a householder, or the details of the tariff may be acquired by the IPM from an energy retailer supplying energy to the household.

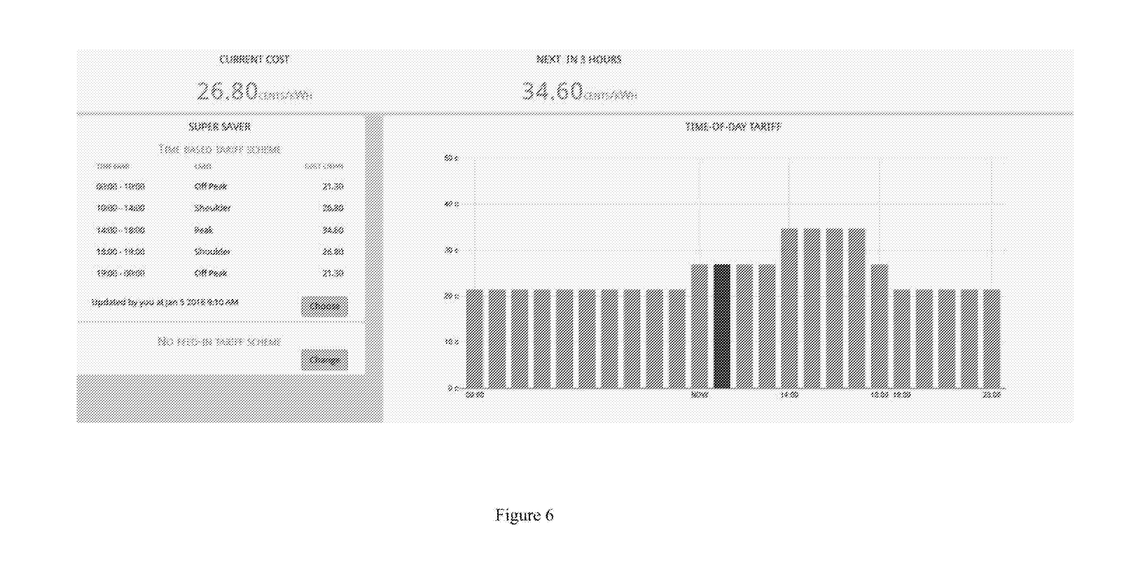

FIG. 6 shows a display from the IPM, showing the time of day variation of the applicable tariff.

Via the user interface, the householder can enter household description data, which describes the makeup of the household, details of the dwelling, and information about the appliances in use in the household. The greater detail the householder is willing to provide, the more accurate comparisons may be mad against other households.

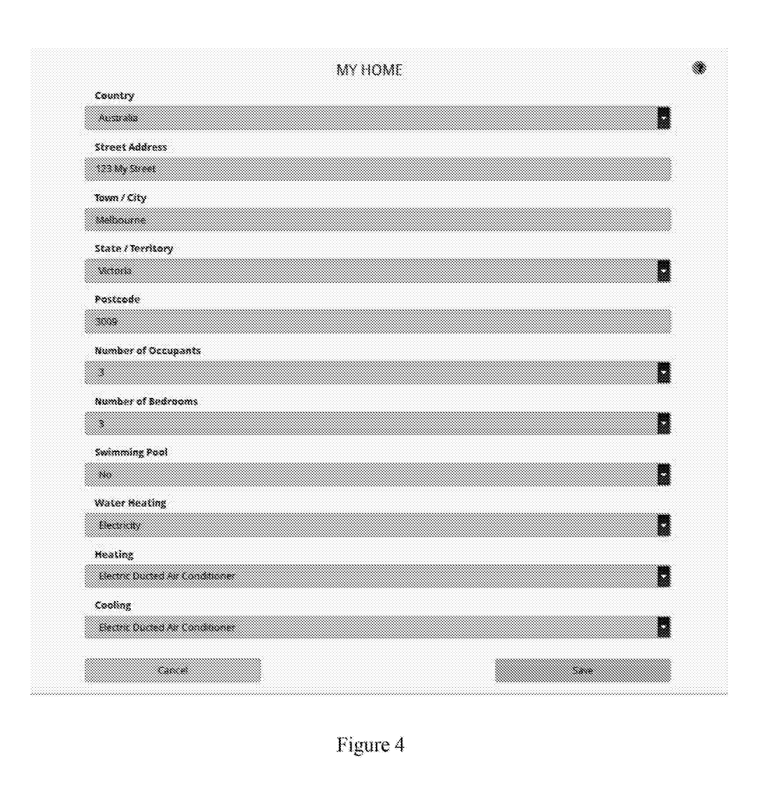

FIG. 4 shows an input screen where a householder may enter information descriptive of their household in order to allow the IPM to characterise the household, and to compare energy usage of the household with energy usage of similar households.

The householder can then choose to compare their energy usage to other households over any selected time period. The households against which the comparison is made may be selected by any combination of energy usage characteristics, household characteristics or geographic characteristics.

Without limitation, these may include
Size and configuration of dwelling
Household makeup
Presence and type of air-conditioning system
Type of Hot Water system
Presence and type of swimming pool equipment
Type of heating system
Type of cooking system
Type of lighting system
Physical location

This then allows the householder to compare their energy usage against similar households to see how they compare in a like for like scenario.

Selection of similar households may be made directly by the householder, or the IPM may select one or a group of households as the comparison target based on the household description data.

The IPM compares the energy usage of the households selected by the householder or by the IPM as being similar according to these criteria with the energy usage of the target household. The differences are displayed to the householder. The householder is shown in what way their household differs from similar households with different energy consumption in terms of the differences in the technology utilised in other households in order to highlight reasons as to why their energy consumption is different. This will then allow the householder to evaluate energy efficient products and technologies which may be of value to them.

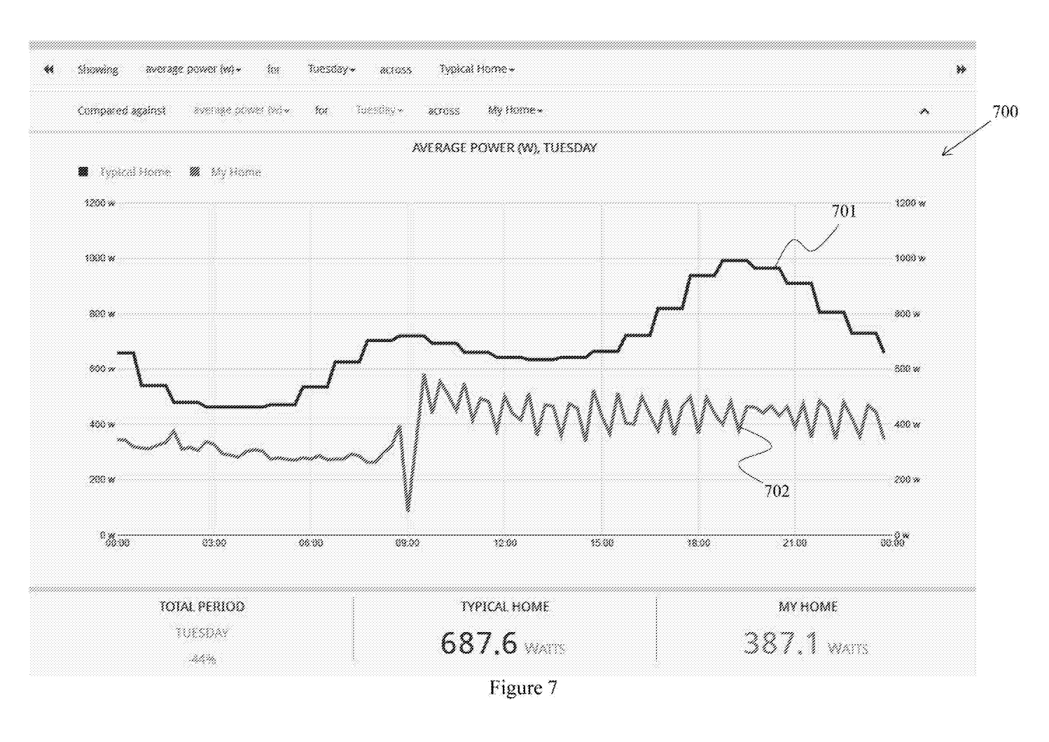

FIG. 7 shows a display 700 from the IPM of a comparison of a household with a typical household. There is a graph which shows average power used over a specific day. The power usage averaged over a group of similar homes is plotted 701 as the usage of a typical home. The actual power usage of the household is plotted 702 a “my home”.

The householder, in this case, is reassured that their power usage is well controlled, compared to other similar households.

Similarly the IPM will undertake this analysis for individual householders to provide them with regular (or as requested by the householder) detailed analysis of their energy usage compared to similar homes. The IPM can provide recommended energy efficiency options for the householder which are in use in similar households. Where a similar household has adopted an energy efficiency measure, the energy usage before and after such an adoption is known to the IPM. The IPM can then predict the result of adoption of that same measure by a target household, taking into account the effect of any small differences between the adopting household and the target household.

Links to or information about providers of the recommended technology can be provided to the use interface for display to the householder.

The IPM analyses and compares households. This data is presented to householders for their information, and to allow them to make choices about behavioural changes which will save energy. The results of such changes can be simulated, based on households which have been selected as similar where such behaviours are undertaken.

It is known that behavioural change, while effective and cheap, is difficult to maintain. Accordingly, the IPM is also able to provide recommendations for solutions which may be higher cost, but which do not require the effort of changing household habits.

The IPM may recommend retrofit appliance control solutions which automate the recommended changes in appliance control. This allows the householder to benefit from the energy savings of such control changes without the need to change habits.

Where the IPM is able to identify particular appliances, these may be identified as being inefficient compared to other appliances which would perform the same function. For example, an older, inefficient refrigerator may be identified. The IPM is able to recommend replacement appliances with superior energy efficiency. The user interface may display links to information about such appliances and information from providers of such appliances. In an embodiment, replacement appliances can be ordered via the user interface, and installation arranged.

The IPM provides the householder with a choice of a range of solutions. These may include less expensive options which involve only changes to energy use habits. Basic home automation such as the use of programmable power switches may be suggested. At the most expensive the replacement of older, less energy efficient appliances with new, efficient appliances may be suggested.

The IPM provides an ongoing energy audit function which detects energy inefficiencies in the household and provides recommendations for solutions.

The IPM can provide the householder with validated information concerning energy efficiency solution payback periods.

The IPM has access to data over a large number of households, allowing simulations of the power savings from installation of control measures or of new appliances to be made with considerable accuracy, by comparing the performance of those measures or appliances in similar households. This allows payback periods to be calculated with accuracy.

One method for reducing electricity bills by reducing energy supplied by an energy retailer is the installation of solar or wind electricity generation capacity, with or without accompanying energy storage capacity such as batteries. The cost of such installations is relatively high, and is affected by many variables. It is difficult to predict the payback of such generation capacity installations and to calculate whether an installation of a particular type or size is economically advantageous. Where the electricity utility provides energy under a time of day tariff, but also pays a feed-in tariff for some or all energy generated by the household generation capacity, then household habits and energy usage patterns must be factored in. The sensor hub receives electricity generation data from the generation installation. The IPM is thus able to make recommendations and predictions about the performance of any contemplated generation installation, based on real world experience of comparable households.

The sensor hub may also contribute to allowing the household to participate in demand response (DR) events. Such events occur when an electricity supply utility has a requirement to reduce electricity demand for a relatively short period. This requirement is communicated in various ways, but in general some rebate, payment or other benefit is available to energy users who are able to make the requested reduction in energy consumption.

The sensor hub is able to monitor household loads to locate large loads in the home including without limitation, air-conditioning installations and swimming pool pumps that are operated during periods where DR control would be valuable. Finding these homes and selectively marketing to them automated control solutions so that they can receive financial or other incentives from participation in future DR events is of value for the householder. An advantage is also available to the energy supply utility. The utility can locate and target customers and customer groups for marketing DR solutions instead of simply providing a blanket DR effort across all customers where some will yield demand reduction benefits and others will not.

In an embodiment the ACM for a particular appliance may be integrated into the appliance at manufacture. The sensor hub may include protocols necessary to communicate with the integrated ACM, or the sensor hub may be able to be programmed in the field, including by the ACM, to include the necessary communications protocols.

In a yet further embodiment, the sensor hub may be provided as a web site provided by the IPM, which may be accessed by a user using a general purpose web browser. In this case the appliances may be provided with means to individually access the internet in order to communicate with the sensor hub. The Smartmeter data may be provided directly to the sensor hub or IPM by an energy retailer or distributor, being the owner or controller of the Smartmeter data. In an embodiment, the web site may be hosted by an energy retailer or distributor.

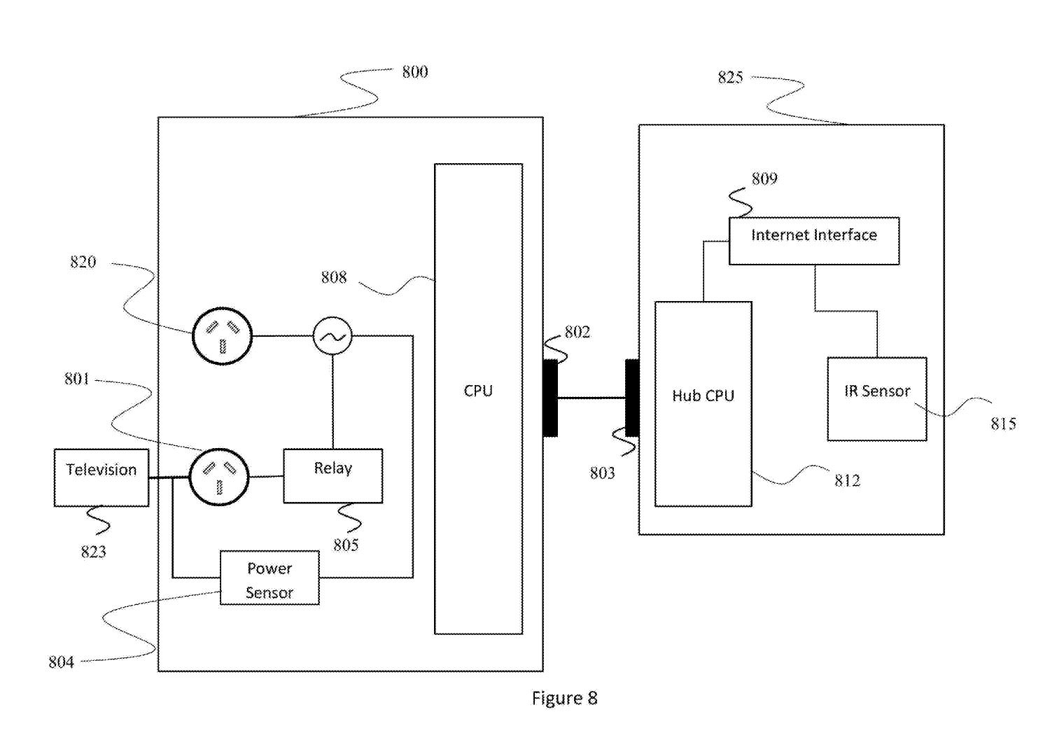

Referring to FIG. 8, there is shown a block diagram of an embodiment of the invention showing the operational units of the SPC.

In use the SPC operates to provide power to the television. The power sensor monitors the power drawn by the television. The power sensor may monitor the current drawn through the Controlled and Monitored Outlet, or both current and voltage may be monitored. Phase angle may also be monitored.

The monitored power draw is used to determine the power state of the television. In an embodiment, a significant drop in the magnitude of the power draw is used to determine that a low power standby mode has been entered. Other characteristics of the power use may be used to determine that the television is not in use. This may be the presence, absence or a defined pattern of small fluctuations of the power draw.

There is provided a SPC body module 800, which houses the electrical and switching elements of the SPC.

SPC Body Module 800 may include Uncontrolled Outlet 820, which provided electrical power at all times when the SPC is plugged in. There is provided Controlled Outlet 801, where the electricity supply to this Controlled Outlet 801 is controlled by relay 805. The power drawn through Controlled Outlet 801 and optionally Uncontrolled Outlet 820 is monitored by power sensor 804.

There is provided a sensor hub 825, which has IR Sensor 815 which detects usage of IR remote control devices. The sensor hub also includes internet interface 809 and Hub CPU 812.

The SPC Body Module 800 further includes module connector 802. A module connector 803 is provided on the sensor hub 825 which is adapted to connect to the module connector 802 on the SPC Body Module 800. These connectors provide data connection between the SPC hub and body units. The connection also provides power to the sensor hub.

SPC Body Module 800 includes CPU 808. The data from power sensor 804 is provided to the CPU 808. The data from IR sensor 815 is provided, via the Hub CPU to the CPU 808. The Hub CPU may analyse the raw data received from the IR Sensor in order to determine that it is a valid IR signal. Only valid IR Signals will be communicated, as data, to the CPU 808. For example, “rouge” IR from such things as CFL lamps or daylight may be detected by the IR Sensor. The Hub CPU analyses the received raw data to determine that the detected signal is in fact a signal from a television or an AV unit remote control. Only when a valid signal is detected is data passed to the CPU 808.

In a preferred embodiment, the CPU 808 is the CPU which controls all of the functions of the SPC, the CPU having been programmed to provide SPC analysis. In other embodiments the Hub CPU 812 may provide the control of the SPC function.

The CPU 808 analyses data from Power Sensor 804 and the Hub CPU 812 to determine when appliances connected to the Controlled Outlet 801, such as television 823, are in a low power standby state or an Active Standby state. When such a determination is made, the CPU 808 controls relay 803 to remove the electricity supply from the Controlled Outlet 801 and thus from the television 823 and any other appliances connected to the Controlled Outlet 801. This causes a saving of energy.

When a user again wishes to use the television, the use of the IR remote control is detected by the sensor hub, and communicated to the CPU 808. CPU 808 operates to restore electrical power to Controlled outlet 801, and thus to television 823.

The CPU may be programmed to keep track of the power consumption of the monitored load, both when the load is using full power and when it is in a low power standby state. Information concerning the number of times the power to the load is interrupted may be recorded. Whether the power was interrupted because the television was in a low power standby mode, or because the television was determined to not be in use may also be recorded. This data may be used to calculate or estimate the energy savings achieved by the SPC. This information may be transmitted via the communication interface to an external party such as an energy retailer.

Where reference has been made to infra-red remote controls and corresponding infra-red sensors, it will be understood that any form of remote control and corresponding sensors, including, without limitation, radio frequency remote controls, may be employed.

The invention has been described in terms of a residential entity, described as a household. However, the invention may be equally applied to commercial or factory entities, or any other discretely measureable, multi-load installation. The term “household” as used herein is intended also to cover such entities and installations.

Although the invention has been herein shown and described in what is conceived to be the most practical and preferred embodiments, it is recognised that departures can be made within the scope of the invention, which is not to be limited to the details described herein but is to be accorded the full scope of the disclosure so as to embrace any and all equivalent devices and apparatus.

1-20. (canceled)

21. A sensor hub for household energy management, the sensor hub:
a. including an environmental sensor configured to sense the environment within a household;
b. configured to provide:
(1) a usage data communications link to a metering device configured to measure the electricity consumption of the household, and
(2) a remote data communications link to a remotely located intelligent power manager.

22. The sensor hub of claim 21 wherein the environmental sensor is one or more of:
a. a temperature sensor,
b. a humidity sensor,
c. an infra-red light detector,
d. a visible light detector, and
e. a proximity detector.

23. The sensor hub of claim 21 wherein the metering device configured to measure the electricity consumption of the household is one of:
a. a Smartmeter, and
b. a current clamp.

24. The sensor hub of claim 21 wherein the sensor hub is further configured to provide a user interface communications link to a mobile computing device having a user interface for the sensor hub.

25. The sensor hub of claim 21 wherein the sensor hub is further configured to provide a control communications link to a standby power controller.

26. The sensor hub of claim 25 wherein the sensor hub:
a. includes a detector adapted to detect use of an audio visual remote control unit, and
b. is further configured to provide an indication of detected use of the audio visual remote control unit to the standby power controller via the control communications link.

27. The sensor hub of claim 26 wherein the standby power controller includes a timer configured:
a. to remove power from a controlled power outlet after a predefined period has elapsed since the standby power controller was provided with an indication of detected use of the audio visual remote control unit, and
b. to reset when the standby power controller is provided with an indication of detected use of the audio visual remote control unit.

28. The sensor hub of claim 26 wherein the sensor hub is configured to receive data characterizing the operation of the standby power controller.

29. The sensor hub of claim 21 further configured to transmit usage data describing the energy consumption of the household to the intelligent power manager via the remote data communications link.

30. A method of using the sensor hub of claim 21 including the steps of:
a. the sensor hub transmitting usage data describing the energy consumption of the household to the intelligent power manager via the remote data communications link, and
b. the intelligent power manager determining from the usage data:
(1) the identity of, and
(2) the energy use of,
an individual appliance in the household.

31. The method of claim 30 further including the steps of:
a. the intelligent power manager:
(1) determining whether a more efficient version of the individual appliance is available, and
(2) transmitting to the sensor hub information regarding the more efficient version;
b. the sensor hub displaying to a householder at least some of the information regarding the more efficient version.

32. The method of claim 30 further including the step of the intelligent power manager receiving household characteristics information from the household, the household characteristics information including one or more of:
a. household demographic makeup,
b. household dwelling characteristics, and
c. household geographic location.

33. The method of claim 32 wherein the intelligent power manager receives household characteristics information from several households.

34. The method of claim 33 further including the steps of:
a. the intelligent power manager:
(1) determining similar households based on a predefined degree of similarity for one or more household characteristics;
(2) determining, from the usage data of the similar households, an average value for at least some of the usage data;
(3) determining variance information for one of the households, the variance information characterizing one or more differences between the one household's usage data and the average value; and
(4) transmitting the variance information to the sensor hub in the one household;
b. the sensor hub displaying to the householder at least some of the variance information.

35. The method of claim 34 further including the steps of:
a. the intelligent power manager:
(1) defining a reason for the differences characterized by the variance information, and
(2) transmitting the reason to the sensor hub in the one household;
b. the sensor hub displaying the reason to the householder.

36. The method of claim 35 further including the sensor hub displaying a suggestion to the householder, wherein the suggestion reduces the differences between the one household's usage data and the average value.

37. A sensor hub for household energy management, the sensor hub including:
a. an environmental sensor configured to sense the environment within a household, the environmental sensor being one or more of:
(1) a temperature sensor,
(2) a humidity sensor,
(3) an infra-red light detector,
(4) a visible light detector, and
(5) a proximity detector;
b. a usage data communications link communicating usage data from a metering device to the sensor hub, the usage data describing the energy consumption of the household;
c. a remote data communications link communicating:
(1) at least some of the usage data to, and
(2) a suggestion for reducing the energy consumption of the household from,
a remotely located intelligent power manager.

38. The sensor hub of claim 37 further including a control communications link communicating environmental sensor data to a standby power controller.

39. The sensor hub of claim 37 further including a user interface communications link to a mobile computing device having a user interface for the sensor hub.
